(19) United States
(12) Patent Application Publication
(10) Pub. No.: US 2010/0014368 A1
(43) Pub. Date: Jan. 21, 2010

(54) SYSTEM THAT INCREASES DATA EYE WIDTHS

(76) Inventors: Peter Schneider, Williston, VT (US); Jorge Calle, Cary, NC (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/174,885

(22) Filed: Jul. 17, 2008

(51) Int. Cl. G11C 29/00; G11C 7/00

(52) U.S. Cl. 365/201; 365/189.011

(57) ABSTRACT

One embodiment provides a system including an integrated circuit configured to receive a signal and invert first read data bits based on the signal. The integrated circuit provides inverted first read data bits that increase data eye widths of second read data bits adjacent the inverted first read data bits.

### BACKGROUND

Typically, a computer system includes a number of integrated circuits that communicate with one another to perform system applications. Often, the computer system includes a controller, such as a micro-processor, and one or more memories, such as a random access memory (RAM). The RAM can be any suitable type of RAM, such as RAM referred to as dynamic RAM (DRAM), double data rate DRAM (DDR-DRAM), double data rate synchronous DRAM (DDR-SDRAM), and graphics DDR-DRAM (GDDR-DRAM).

Integrated circuit speeds continue to increase and the amount of data communicated between circuits continues to increase to meet the demands of system applications. As data volume increases, the industry continues to develop larger memory sizes to accommodate increased data requirements. These trends of increasing circuit speeds, increasing data volume, and larger memory sizes are expected to continue into the future. As data volume increases, higher bandwidth communication links are developed to prevent data communication bottlenecks between circuits. Higher bandwidth communication links can be made by increasing input/output (I/O) data bit speeds and reducing clock cycle times.

Some test systems have a difficult time capturing read data bits that are output during high speed testing of an integrated circuit, such as a DRAM. The integrated circuit can be in wafer form or a packaged integrated circuit chip. Output signal distortion decreases the reliability of a test system and can result in an increase in false failures. Data eye distortions include data eye shifts and a narrowing of the data eye, where data eye shifts may be due to deviations in the process and a narrowing of the data eye may be due to a reduced clock cycle time and/or an increased contribution from parasitic devices related to test equipment, such as probe cards. In addition, noise on a test system, which decreases signal margin, and tester timing variations can result in errors in capturing the read data bits.

For these and other reasons there is a need for the present invention.

### SUMMARY

The present disclosure describes a system including an integrated circuit that increases the data eye widths of read data bits. One embodiment provides a system including an integrated circuit configured to receive a signal and invert first read data bits based on the signal. The integrated circuit provides inverted first read data bits that increase data eye widths of second read data bits adjacent the inverted first read data bits.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a test system.

FIG. 2 is a diagram illustrating one embodiment of an integrated circuit that includes a test circuit and an input/output circuit.

FIG. 3 is a timing diagram illustrating the operation of one embodiment of the test system of FIG. 1.

FIG. 4 is a table illustrating the sixteen different data patterns of four read data bits.

FIG. 5 is a timing diagram illustrating the operation of one embodiment of the test system of FIG. 1 that includes a tester that transmits a test signal including a pointer signal.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

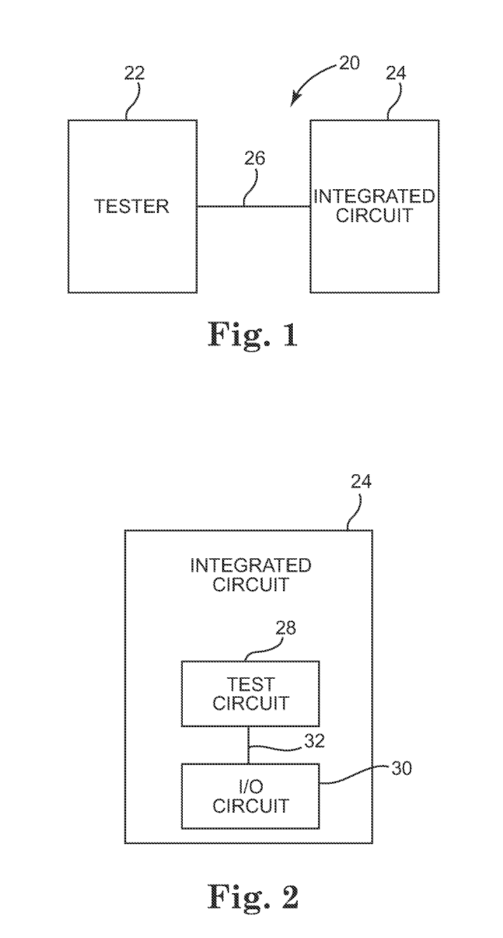

FIG. 1 is a diagram illustrating one embodiment of a test system 20. Test system 20 includes a tester 22 and an integrated circuit 24, which is the device under test (DUT). Tester 22 is electrically coupled to integrated circuit 24 via test path 26. In one embodiment, integrated circuit 24 is part of a semiconductor wafer in wafer form. In one embodiment, integrated circuit 24 is a packaged integrated circuit chip. In one embodiment, integrated circuit 24 is a DRAM. In one embodiment, integrated circuit 24 is a DDR-DRAM. In one embodiment, test path 26 includes suitable test equipment and circuitry, such as one or more test boards, probe cards, and/or cables.

Tester 22 provides data to integrated circuit 24 and receives read data bits from integrated circuit 24 via test path 26. In one embodiment, integrated circuit 24 provides read data bits in data bursts of a suitable size, such as 2 bit, 4 bit, 8 bit, 16 bit, or larger data bursts. In one embodiment, tester 22 tests odd read data bits in one pass and even read data bits in another pass.

Tester 22 provides a test signal to integrated circuit 24 via test path 26. The test signal indicates which read data bits to invert during testing of integrated circuit 24. Integrated circuit 24 receives the test signal and inverts the indicated read data bits. Indicated read data bits are inverted to be in the same state as adjacent read data bits, assuming the indicated and adjacent read data bits are error free. Inverting read data bits to be in the same state as adjacent read data bits increases data eye widths of the adjacent read data bits. Also, inverting read data bits to be in the same state as adjacent read data bits reduces output switching noise in test system 20, which increases noise margin. As a result, false failures are reduced during testing of integrated circuit 24. In one embodiment, the read data bits were previously written into integrated circuit 24 via tester 22. In one embodiment, the read data bits were previously written into integrated circuit 24 via a suitable circuit in integrated circuit 24.

Tester 22 provides a strobe signal to capture received read data bits. In one embodiment, strobe signal timing is adjusted to move the strobe signal closer to the inverted read data bits, which takes advantage of the increased data eye widths.

In one embodiment, the test signal indicates a test mode and the integrated circuit 24 receives the test signal, puts the integrated circuit into the indicated test mode, selects read data bits based on the test mode, and inverts the selected read data bits based on the test mode. In one embodiment, integrated circuit 24 is put into a test mode where every other read data bit in a data burst is inverted, such as the second and fourth read data bits in a data burst of four bits. In one embodiment, integrated circuit 24 is put into a test mode where a selected read data bit in a data burst is inverted, such as the second or the fourth read data bit in a data burst.

In one embodiment, the test signal is a pointer signal and the integrated circuit receives the pointer signal, selects read data bits based on the pointer signal, and inverts the selected read data bits based on the pointer signal.

Test system 20 increases data eye widths, reduces switching noise, and increases noise margin via inverting read data bits to be the same as adjacent read data bits. This reduces false failures and increases reliability of test system 20.

FIG. 2 is a diagram illustrating one embodiment of integrated circuit 24 that includes a test circuit 28 and an input/output circuit 30. Test circuit 28 is electrically coupled to input/output (I/O) circuit 30 via signal path 32. Test circuit 28 controls testing in integrated circuit 24. In one embodiment, test circuit 28 receives the test signals directly from tester 22 via test path 26. In one embodiment, test circuit 28 receives the test signals from tester 22 via another control circuit in integrated circuit 24.

Test circuit 28 receives a test signal from tester 22 and provides data bit inversion signals for inverting selected read data bits. Test circuit 28 provides the data bit inversion signals to I/O circuit 30 via signal path 32. I/O circuit 30 receives the data bit inversion signals and inverts the selected read data bits prior to outputting the read data bits. In one embodiment, I/O circuit 30 includes inverters that are switched into the output path of I/O circuit 30 to invert the selected read data bits while outputting a data burst.

In one embodiment, the test signal indicates a test mode. Test circuit 28 receives the test mode and selects which read data bits to invert based on the test mode. Test circuit 28 provides data bit inversion signals to I/O circuit 30 to invert the selected read data bits. I/O circuit 30 receives the data bit inversion signals and inverts the selected read data bits prior to outputting the read data bits. In one embodiment, test circuit 28 receives a test mode and provides data bit inversion signals to I/O circuit 30 to invert every other read data bit in a data burst based on the test mode. In one embodiment, test circuit 28 receives a test mode and provides data bit inversion signals to I/O circuit 30 to invert a selected read data bit in a data burst based on the test mode.

In one embodiment, test circuit 28 receives pointer signals, where each of the pointer signals points to a selected read data bit. Test circuit 28 provides data bit inversion signals to I/O circuit 30 to invert the selected read data bits based on the pointer signals. I/O circuit 30 receives the data bit inversion signals and inverts the selected read data bits prior to outputting the read data bits.

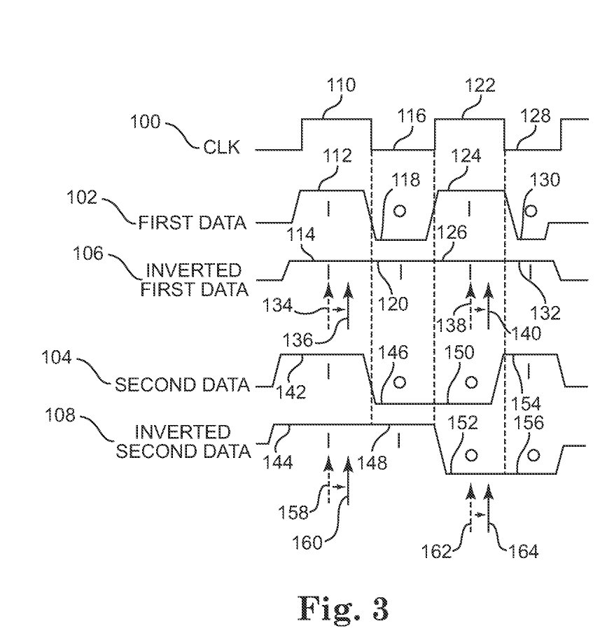

FIG. 3 is a timing diagram illustrating the operation of one embodiment of test system 20 of FIG. 1. Tester 22 transmits a test signal that indicates a test mode to integrated circuit 24 via test path 26. Integrated circuit 24 reads data from memory and, based on the test mode, inverts selected read data bits. The inverted read data bits are adjacent other read data bits and integrated circuit 24 outputs the inverted and adjacent read data bits in output data bursts.

The test mode provided to integrated circuit 24 via tester 22 corresponds to the data bit pattern or patterns being tested. For example, to test a data bit pattern of alternating high and low data bits, tester 22 transmits a test mode to integrated circuit 24 to invert every other read data bit. In one embodiment, integrated circuit 24 inverts every even read data bit. In one embodiment, integrated circuit 24 inverts every odd read data bit. In one embodiment, integrated circuit 24 inverts every even read data bit for one test pass and every odd read data bit for another test pass.

In one embodiment, tester 22 tests output read data bits in two test passes such that in one test pass tester 22 tests odd data bits in the output data bursts and in another test pass tester 22 tests even data bits in the output data bursts. In one test mode and for one test pass, integrated circuit 24 inverts every even data bit and tester 22 tests every odd data bit. In another test mode and for the other test pass, integrated circuit 24 inverts every odd data bit and tester 22 tests every even data bit.

In the illustrated example, integrated circuit 24 is a DRAM that provides a data burst of four read data bits. Integrated circuit 24 outputs one data bit in each half cycle of clock signal CLK at 100. Two data bit patterns are illustrated. In the first data bit pattern 102, integrated circuit 24 reads an alternating data bit pattern of 1-0-1-0 from its memory. In the second data bit pattern 104, integrated circuit 24 reads a data bit pattern of 1-0-0-1 from its memory.

Tester 22 transmits a test mode to integrated circuit 24 to invert every even read data bit, where the data bits are numbered one through four and the second and fourth read data bits are inverted. The resulting inverted first data bit pattern 106 is output in a data burst of four read data bits and the resulting inverted second data bit pattern 108 is output in another data burst of four read data bits.

At 110, clock signal CLK at 100 is at a high voltage level and the first read data bit 112 in the first data bit pattern 102 is at a high voltage level. Integrated circuit 24 does not invert the first read data bit 112 and the first read data bit 114 in the inverted first data bit pattern 106 is at a high voltage level. At 116, clock signal CLK at 100 is at a low voltage level and the second read data bit 118 in the first data bit pattern 102 is at a low voltage level. Integrated circuit 24 inverts the second read data bit 118 and provides a high voltage level for the second read data bit 120 in the inverted first data bit pattern 106. At 122, clock signal CLK at 100 is at a high voltage level and the third read data bit 124 in the first data bit pattern 102 is at a high voltage level. Integrated circuit 24 does not invert the third read data bit 124 and the third read data bit 126 in the inverted first data bit pattern 106 is at a high voltage level. At 128, clock signal CLK at 100 is at a low voltage level and the fourth read data bit 130 in the first data bit pattern 102 is at a low voltage level. Integrated circuit 24 inverts the fourth read data bit 130 and provides a high voltage level for the fourth read data bit 132 in the inverted first data bit pattern 106.

Tester 22 adjusts strobe timing to move the test strobe from a position at 134 to the position at 136 to test the first read data bit 114 in the inverted first data bit pattern 106. Tester 22 adjusts strobe timing to move the test strobe from a position at 138 to the position at 140 to test the third read data bit 126 in the inverted first data bit pattern 106. The data eye widths of the first read data bit 114 and the third read data bit 126 in the inverted first data bit pattern 106 are increased over the data eye widths of the first read data bit 112 and the third read data bit 124 in the first data bit pattern 102. The increase in the data eye widths reduces false failures due to narrow data eyes and tester timing variations. In addition, reducing output switching reduces noise and improves noise margin to provide more reliable testing conditions via test system 20.

For the second data bit pattern 104, clock signal CLK at 100 is at a high voltage level at 110 and the first read data bit 142 in the second data bit pattern 104 is at a high voltage level. Integrated circuit 24 does not invert the first read data bit 142 and the first read data bit 144 in the inverted second data bit pattern 108 is at a high voltage level. At 116, clock signal CLK at 100 is at a low voltage level and the second read data bit 146 in the second data bit pattern 104 is at a low voltage level. Integrated circuit 24 inverts the second read data bit 146 and provides a high voltage level for the second read data bit 148 in the inverted second data bit pattern 108. At 122, clock signal CLK at 100 is at a high voltage level and the third read data bit 150 in the second data bit pattern 104 is at a low voltage level. Integrated circuit 24 does not invert the third read data bit 150 and the third read data bit 152 in the inverted second data bit pattern 108 is at a low voltage level. At 128, clock signal CLK at 100 is at a low voltage level and the fourth read data bit 154 in the second data bit pattern 104 is at a high voltage level. Integrated circuit 24 inverts the fourth read data bit 154 and provides a low voltage level for the fourth read data bit 156 in the inverted second data bit pattern 108.

Tester 22 adjusts strobe timing to move the test strobe from a position at 158 to the position at 160 to test the first read data bit 144 in the inverted second data bit pattern 108. Tester 22 adjusts strobe timing to move the test strobe from a position at 162 to the position at 164 to test the third read data bit 152 in the inverted second data bit pattern 108. The data eye widths of the first read data bit 144 and the third read data bit 152 in the inverted second data bit pattern 108 are increased over the data eye widths of the first read data bit 142 and the third read data bit 150 in the second data bit pattern 104. The increase in the data eye widths reduces false failures due to narrow data eyes and tester timing variations. In addition, reducing output switching reduces noise and improves noise margin to provide more reliable testing conditions via test system 20.

In other embodiments, tester 22 provides a test signal that indicates another test mode to integrated circuit 24 to invert other selected read data bits. In one embodiment, a test mode is provided to integrated circuit 24 to invert only the second read data bit in a data burst. In one embodiment, a test mode is provided to integrated circuit 24 to invert only the fourth read data bit in a data burst. In one embodiment, a test mode is provided to integrated circuit 24 to invert only the first read data bit in a data burst. In one embodiment, a test mode is provided to integrated circuit 24 to invert only the third read data bit in a data burst.

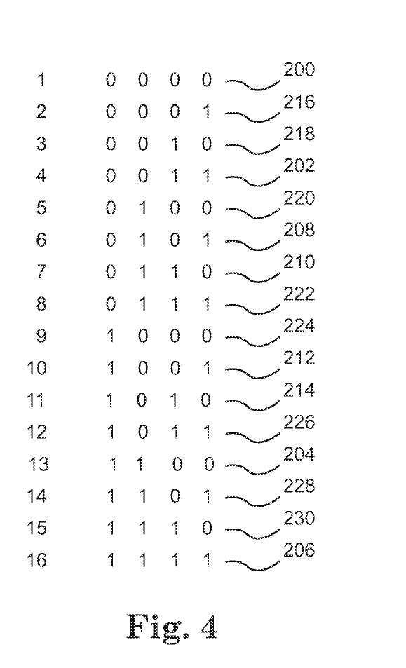

FIG. 4 is a table illustrating the sixteen different data patterns of four read data bits. In four data patterns at 200, 202, 204, and 206 either all of the read data bits have the same logic value or the first two read data bits have one logic value and the last two read data bits have the other logic value. The read data bits in the four data patterns at 200, 202, 204, and 206 have wide data eyes and produce little switching noise without inverting read data bits via test system 20.

For the four data patterns at 208, 210, 212, and 214, tester 22 provides a test signal including a test mode to invert every other data bit. Inverting every other read data bit in the four data patterns at 208, 210, 212, and 214 increases data eye widths and reduces switching noise, as described above in the description of FIG. 3. Increasing data eye widths reduces false failures and reducing switching noise improves noise margin to provide more reliable testing conditions.

Each of the other eight read data patterns at 216, 218, 220, 222, 224, 226, 228, and 230 have a lone read data bit that has a different logic value than the rest of the read data bits. In embodiments of test system 20, tester 22 provides test signals that include test modes to invert selected read data bits, such as only one read data bit out of the four read data bits. This increases data eye widths to reduce false failures and, in some cases, it reduces switching noise to improve noise margin and provide more reliable testing conditions.

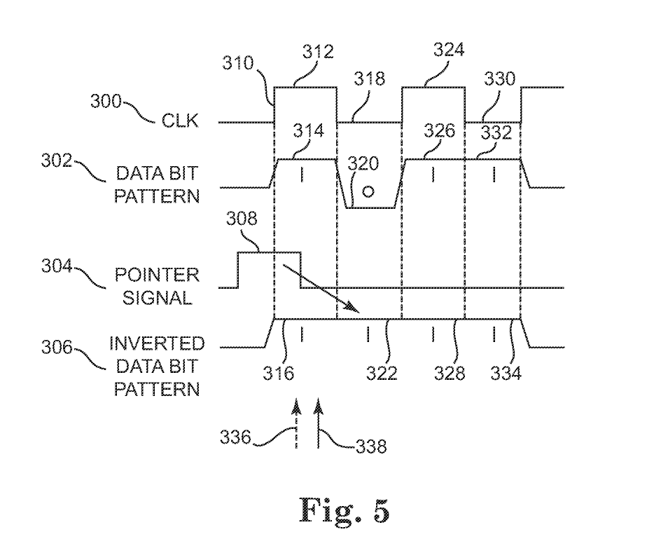

FIG. 5 is a timing diagram illustrating the operation of one embodiment of test system 20 of FIG. 1. Tester 22 transmits a test signal including a control or pointer signal to integrated circuit 24 via test path 26. The pointer signal identifies which read data bits are inverted via integrated circuit 24. Integrated circuit 24 reads data from memory and, based on the pointer signal, inverts selected read data bits. The inverted read data bits are adjacent other read data bits and integrated circuit 24 outputs the inverted and adjacent read data bits in output data bursts. In one embodiment, tester 22 tests output read data bits in two test passes such that in one test pass tester 22 tests odd data bits in the output data bursts and in another test pass tester 22 tests even data bits in the output data bursts.

In the illustrated example, integrated circuit 24 is a DRAM that provides a data burst of four read data bits. Integrated circuit 24 outputs one data bit in each half cycle of clock signal CLK at 300. Integrated circuit 24 reads a data bit pattern 302 of 1-0-1-1 from its memory. Tester 22 transmits pointer signal 304 to integrated circuit 24 to invert the second read data bit, where the read data bits are numbered one through four and the second read data bit is inverted. The resulting inverted data bit pattern 306 is output in a data burst of four read data bits.

Tester 22 transmits a pulse 308 in pointer signal 304. Integrated circuit 24 receives pulse 308 at the rising edge 310 of clock signal CLK at 300 and inverts the second read data bit based on the pulse 308, which is a latency of one half of a clock cycle. In other embodiments, the latency of pulse to inverted read data bit is a suitable number, such as one, one and a half, two, or more clock cycles.

At 312, clock signal CLK at 300 is at a high voltage level and the first read data bit 314 in data bit pattern 302 is at a high voltage level. Integrated circuit 24 does not invert the first read data bit 314 and the first read data bit 316 in the inverted data bit pattern 306 is at a high voltage level. At 318, clock signal CLK at 300 is at a low voltage level and the second read data bit 320 in data bit pattern 302 is at a low voltage level. Integrated circuit 24 inverts the second read data bit 320 and provides a high voltage level for the second read data bit 322 in the inverted data bit pattern 306. Integrated circuit 24 receives pulse 308 at the rising edge 310 of clock signal CLK at 300 and inverts the second read data bit based on pulse 308.

At 324, clock signal CLK at 300 is at a high voltage level and the third read data bit 326 in data bit pattern 302 is at a high voltage level. Integrated circuit 24 does not invert the third read data bit 326 and the third read data bit 328 in the inverted data bit pattern 306 is at a high voltage level. At 330, clock signal CLK at 300 is at a low voltage level and the fourth read data bit 332 in data bit pattern 302 is at a high voltage level. Integrated circuit 24 does not invert the fourth read data bit 332 and the fourth read data bit 334 in the inverted data bit pattern 306 is at a high voltage level.

Tester 22 adjusts strobe timing to move the test strobe from a position at 336 to the position at 338 to test the first read data bit 316 in the inverted data bit pattern 306. The data eye width of the first read data bit 316 is increased over the data eye width of the first read data bit 314 in data bit pattern 302. Increasing data eye widths reduces false failures due to narrow data eyes and tester timing variations. In addition, reducing output switching reduces noise and improves noise margin to provide more reliable testing conditions via test system 20.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system, comprising:
an integrated circuit configured to receive a signal and invert first read data bits based on the signal to provide inverted first read data bits that increase data eye widths of second read data bits adjacent the inverted first read data bits.

2. The system of claim 1, wherein one of the inverted first read data bits is in the same state as one of the second read data bits to increase the data eye width of the one of the second read data bits.

3. The system of claim 1, wherein the integrated circuit provides the inverted first read data bits and the second read data bits in read data bursts.

4. The system of claim 1, wherein the signal indicates a test mode of the integrated circuit and the integrated circuit selects the first read data bits and inverts the selected first read data bits based on the test mode.

5. The system of claim 4, wherein the integrated circuit inverts every other read data bit based on the test mode.

6. The system of claim 4, wherein the integrated circuit inverts one read data bit of at least four read data bits based on the test mode.

7. The system of claim 1, wherein the signal is a control signal and the integrated circuit selects the first read data bits and inverts the selected first read data bits based on the control signal.

8. The system of claim 1, wherein the integrated circuit comprises:
a test circuit configured to receive the signal and provide data bit inversion signals; and
an input/output circuit configured to receive the data bit inversion signals and invert the first read data bits based on the data bit inversion signals.

9. The system of claim 1, wherein the integrated circuit is a dynamic random access memory.

10. A system, comprising:
a tester configured to test first read data bits and provide a signal that indicates second read data bits; and
an integrated circuit configured to receive the signal and invert the second read data bits to reduce false failures in testing the first read data bits.

11. The system of claim 10, wherein the tester is configured to test odd read data bits in one pass and even read data bits in another pass.

12. The system of claim 10, wherein the tester is configured to provide a strobe signal that is adjusted toward an inverted second read data bit to test an adjacent first read data bit.

13. The system of claim 10, wherein the signal indicates a test mode and the integrated circuit is configured to put the integrated circuit into the test mode, select the second read data bits based on the test mode, and invert the second read data bits based on the test mode.

14. The system of claim 10, wherein the signal is a pointer signal and the integrated circuit is configured to select the second read data bits and invert the second read data bits based on the pointer signal.

15. A system, comprising:
means for receiving a signal; and
means for inverting first read data bits based on the signal to provide inverted first read data bits that increase data eye widths of second read data bits adjacent the inverted first read data bits.

16. The system of claim 15, wherein:
the means for receiving a signal comprises means for receiving a test mode; and
the means for inverting comprises means for selecting the first read data bits and inverting the first read data bits based on the test mode.

17. The system of claim 15, wherein:
the means for receiving a signal comprises means for receiving a pointer signal; and
the means for inverting comprises means for selecting the first read data bits and inverting the first read data bits based on the pointer signal.

18. A method of testing comprising:
receiving a signal; and
inverting first read data bits based on the signal to provide inverted first read data bits that increase data eye widths of second read data bits adjacent the inverted first read data bits.

19. The method of claim 18, comprising:
providing read data bursts that include the inverted first read data bits and the second read data bits.

20. The method of claim 18, wherein:
receiving a signal comprises receiving a test mode; and
inverting first read data bits comprises selecting the first read data bits and inverting the first read data bits based on the test mode.

21. The method of claim 20, comprising one of:
inverting every other read data bit based on the test mode; and
inverting one read data bit of at least four read data bits based on the test mode.

22. The method of claim 18, wherein:
receiving a signal comprises receiving a pointer signal; and
inverting first read data bits comprises selecting the first read data bits and inverting the first read data bits based on the pointer signal.

23. A method of testing an integrated circuit comprising:
testing first read data bits;
providing a signal that indicates second read data bits;
receiving the signal; and
inverting the second read data bits to reduce false failures in the testing of the first read data bits.

24. The method of claim 23, comprising:
providing a strobe signal that is adjusted toward an inverted second read data bit to test an adjacent first read data bit.

25. The method of claim 23, wherein providing a signal comprises one of:
providing a test mode in the signal; and
providing a pointer signal in the signal.
